(19) United States
(12) Patent Application Publication
(10) Pub. No.: US 2024/0333250 A1
(43) Pub. Date: Oct. 3, 2024

(54) ACOUSTIC WAVE DEVICE

(71) Applicant: Murata Manufacturing Co., Ltd., Nagaokakyo-shi (JP)

(72) Inventor: Takashi YAMANE, Nagaokakyo-shi (JP)

(21) Appl. No.: 18/678,056

(22) Filed: May 30, 2024

Related U.S. Application Data
(63) Continuation of application No. PCT/JP2022/045102, filed on Dec. 7, 2022.
(60) Provisional application No. 63/286,672, filed on Dec. 7, 2021.

(51) Int. Cl. H03H 9/13; H03H 9/17

(52) U.S. Cl. CPC H03H 9/13; H03H 9/17

(57) ABSTRACT

An acoustic wave device includes a support portion, a piezoelectric layer on the support portion and including a first main surface on a support portion side and a second main surface opposing the first main surface, and at least one IDT on the first main surface of the piezoelectric layer and including electrode finger portions. A cavity portion surrounded by the support portion and the piezoelectric layer is provided. The electrode finger portions of the at least one IDT are located in the cavity portion. At least a portion of an electrode finger portion of the IDT at a position closer to the through hole in one set of the electrode finger portions has a smaller thickness and a larger width than at least a portion of an electrode finger portion at a position farther from the through hole.

### CROSS REFERENCE TO RELATED APPLICATIONS

This application claims the benefit of priority to Provisional Application No. 63/286,672, filed on Dec. 7, 2021, and is a Continuation Application of PCT Application No. PCT/JP2022/045102, filed on Dec. 7, 2022, and. The entire contents of each application are hereby incorporated herein by reference.

### BACKGROUND OF THE INVENTION

### 1. Field of the Invention

The present invention relates to acoustic wave devices.

### 2. Description of the Related Art

In the related art, an acoustic wave device has been widely used for a filter or the like of a mobile phone. International Publication No. WO2011/052551 describes an example of a piezoelectric device as an acoustic wave device. In the acoustic wave device, a multilayer body of a support, an elastic layer, an inorganic layer, and a piezoelectric thin film is formed. The multilayer body is provided with a void portion. The void portion is surrounded by the piezoelectric thin film and the inorganic layer. An interdigital transducer (IDT) electrode is provided on the piezoelectric thin film such that the IDT electrode overlaps the void portion in plan view.

The void portion is formed by removing a sacrificial layer provided between the piezoelectric thin film and the inorganic layer via etching. It should be noted that an etching window for performing the etching is provided in the piezoelectric thin film.

In the acoustic wave device described in International Publication No. WO2011/052551, the IDT electrode is provided on a main surface of the piezoelectric thin film, which does not face the void portion. However, the IDT electrode may be provided in the void portion. However, in this case, the etching for providing the void portion may cause the corrosion of an electrode finger of the IDT electrode. Therefore, there is a risk that the stability of the electrical characteristics of the acoustic wave device is impaired.

### SUMMARY OF THE INVENTION

Example embodiments of the present invention provide acoustic wave devices in each of which electrical characteristics are able to be stabilized in a configuration in which an IDT is provided in a cavity portion.

An example embodiment of the present invention provides an acoustic wave device including a support portion including a support substrate, a piezoelectric layer on the support portion and including a first main surface located on a support portion side and a second main surface opposing the first main surface, and at least one interdigital transducer (IDT) on the first main surface of the piezoelectric layer and including a plurality of electrode finger portions, in which a cavity portion surrounded by the support portion and the piezoelectric layer is provided, the plurality of electrode finger portions of the at least one IDT are located in the cavity portion, and a through hole is provided in the piezoelectric layer to extend to the cavity portion, and in the plurality of electrode finger portions of the at least one IDT, a dimensional relationship is provided in at least one set of the electrode finger portions, the dimensional relationship being a relationship in which at least a portion of an electrode finger portion at a position closer to the through hole in the one set of the electrode finger portions has a smaller thickness and a larger width than at least a portion of an electrode finger portion at a position farther from the through hole.

According to example embodiments of the present invention, it is possible to provide acoustic wave devices in each of which electrical characteristics are able to be stabilized in a configuration in which an IDT is provided in a cavity portion.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a schematic plan view of an acoustic wave device according to a first example embodiment of the present invention.

FIG. 2 is a schematic cross-sectional view taken along line I-I in FIG. 1.

FIG. 3 is a schematic bottom view showing a configuration of an interdigital transducer (IDT) provided on a first main surface of a piezoelectric layer according to the first example embodiment of the present invention.

FIGS. 4A and 4B are schematic cross-sectional views taken along an electrode finger portion extending direction and showing an IDT electrode forming step and a sacrificial layer forming step in an example of a manufacturing method of the acoustic wave device according to the first example embodiment of the present invention.

FIGS. 5A to 5D are schematic cross-sectional views taken along the electrode finger portion extending direction and showing a first insulating layer forming step, a first insulating layer flattening step, a second insulating layer forming step, and a piezoelectric substrate bonding step in the example of the manufacturing method of the acoustic wave device according to the first example embodiment of the present invention.

FIG. 6A is a schematic cross-sectional view taken along the electrode finger portion extending direction and showing a piezoelectric layer grinding step and a via hole forming step in the example of the manufacturing method of the acoustic wave device according to the first example embodiment of the present invention.

FIG. 6B is a schematic elevational cross-sectional view showing a through hole forming step in the example of the manufacturing method of the acoustic wave device according to the first example embodiment of the present invention. FIG. 6C is a schematic cross-sectional view taken along the electrode finger portion extending direction and showing a wiring electrode forming step and a terminal electrode forming step in the example of the manufacturing method of the acoustic wave device according to the first example embodiment of the present invention.

FIG. 7 is a schematic plan view of an acoustic wave device according to a second example embodiment of the present invention.

FIG. 8 is a schematic cross-sectional view taken along line I-I in FIG. 7.

FIGS. 9A to 9C are schematic cross-sectional views taken along an electrode finger portion extending direction and showing a via hole forming step, a wiring electrode forming step, a terminal electrode forming step, and a frequency adjustment film forming step in an example of a manufacturing method of the acoustic wave device according to the second example embodiment of the present invention.

FIGS. 10A and 10B are schematic elevational cross-sectional views showing a through hole forming step, a sacrificial layer removal step, and an IDT forming step in the example of the manufacturing method of the acoustic wave device according to the second example embodiment of the present invention.

FIG. 11 is a schematic elevational cross-sectional view of an acoustic wave device according to a third example embodiment of the present invention.

FIG. 12 is a schematic elevational cross-sectional view showing a vicinity of a portion of an IDT of the acoustic wave device according to the third example embodiment of the present invention, in an enlarged manner.

FIG. 13 is a schematic elevational cross-sectional view showing a state before a sacrificial layer removal step is performed in an example of a manufacturing method of the acoustic wave device according to the third example embodiment of the present invention.

FIG. 14A is a schematic perspective view showing an appearance of the acoustic wave device using a bulk wave in a thickness shear mode, and FIG. 14B is a plan view showing an electrode structure on a piezoelectric layer.

FIG. 15 is a cross-sectional view of a portion taken along line A-A in of FIG. 14A.

FIG. 16A is a schematic elevational cross-sectional view showing a Lamb wave that propagates through a piezoelectric film of the acoustic wave device, and FIG. 16B is a schematic elevational cross-sectional view showing a bulk wave in a thickness shear mode that propagates through the piezoelectric film of the acoustic wave device.

FIG. 17 is a view showing an amplitude direction of the bulk wave in the thickness shear mode.

FIG. 18 is a view showing resonance characteristics of the acoustic wave device using the bulk wave in the thickness shear mode.

FIG. 19 is a view showing a relationship between d/p and a fractional bandwidth as a resonator in a case where a center-to-center distance of electrodes adjacent to each other is p and a thickness of a piezoelectric layer is d.

FIG. 20 is a plan view of the acoustic wave device using the bulk wave in the thickness shear mode.

FIG. 21 is a view showing resonance characteristics of an acoustic wave device of a reference example in which a spurious wave appears.

FIG. 22 is a view showing a relationship between a fractional bandwidth and a phase rotation amount of an impedance of the spurious wave standardized at 180 degrees as a magnitude of the spurious wave.

FIG. 23 is a view showing a relationship between d/2p and a metallization ratio MR.

FIG. 24 is a view showing a map of the fractional bandwidth with respect to Euler angles (0°, θ, ψ) of LiNbO₃ in a case where d/p is infinitely close to 0.

FIG. 25 is a partially cutaway perspective view showing the acoustic wave device using the Lamb wave.

### DETAILED DESCRIPTION OF THE EXAMPLE EMBODIMENTS

Hereinafter, the present invention will be clarified by describing example embodiments of the present invention with reference to the accompanying drawings.

Each of example embodiments described in the present specification is merely an example, and partial replacement or combination of the configurations can be made between different example embodiments.

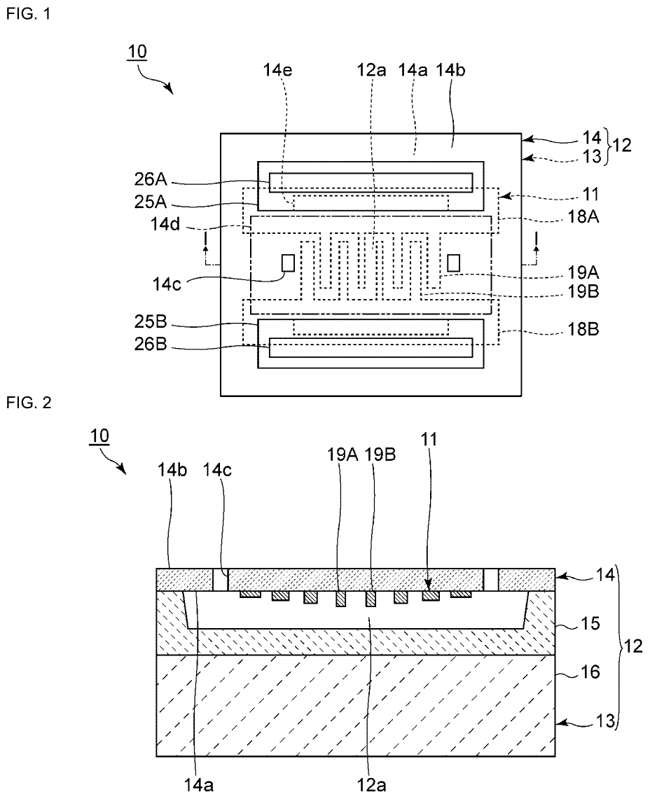

FIG. 1 is a schematic plan view of an acoustic wave device according to a first example embodiment of the present invention. FIG. 2 is a schematic cross-sectional view taken along line I-I in FIG. 1.

As shown in FIG. 1, the acoustic wave device 10 includes a piezoelectric substrate 12 and an interdigital transducer (IDT) 11. As shown in FIG. 2, the piezoelectric substrate 12 includes a support portion 13 and a piezoelectric layer 14. In the present example embodiment, the support portion 13 includes a support substrate 16 and an insulating layer 15. The insulating layer 15 is provided on the support substrate 16. The piezoelectric layer 14 is provided on the insulating layer 15. However, the support portion 13 may be configured only by the support substrate 16.

The piezoelectric layer 14 includes a first main surface 14a and a second main surface 14b. The first main surface 14a and the second main surface 14b oppose each other. Of the first main surface 14a and the second main surface 14b, the first main surface 14a is located on the support portion 13 side.

As the material of the support substrate 16, for example, a semiconductor such as silicon, a ceramic such as aluminum oxide, or the like can be used. As the material of the insulating layer 15, an appropriate dielectric such as, for example, silicon oxide or tantalum oxide can be used. The piezoelectric layer 14 is, for example, a lithium niobate layer such as a LiNbO₃ layer or a lithium tantalate layer such as a LiTaO₃ layer.

As shown in FIG. 2, a recess portion is provided in the insulating layer 15. The piezoelectric layer 14 is provided on the insulating layer 15 to close the recess portion. Accordingly, a hollow portion surrounded by the support portion 13 and the piezoelectric layer 14 is formed. The hollow portion is a cavity portion 12a. In the present example embodiment, the support portion 13 and the piezoelectric layer 14 are disposed such that a portion of the support portion 13 and a portion of the piezoelectric layer 14 oppose each other with the cavity portion 12a interposed therebetween. More specifically, the insulating layer 15 and the piezoelectric layer 14 are disposed such that a portion of the insulating layer 15 and a portion of the piezoelectric layer 14 oppose each other with the cavity portion 12a interposed therebetween. However, the recess portion in the support portion 13 may be provided over the insulating layer 15 and the support substrate 16.

The IDT 11 is provided on the first main surface 14a of the piezoelectric layer 14. The IDT 11 is located in the cavity portion 12a. The acoustic wave device 10 according to the present example embodiment is an acoustic wave resonator configured to use a bulk wave in a thickness shear mode, for example. However, the acoustic wave device 10 may be configured to use a plate wave, for example.

As shown in FIG. 1, a portion of the piezoelectric layer 14 overlapping the cavity portion 12a in plan view is a membrane portion 14d. In the present specification, “in plan view” means that the support portion 13 and the piezoelectric layer 14 are viewed along a laminating direction from a direction corresponding to an up direction in FIG. 2. On the other hand, “in bottom view” means that the support portion 13 and the piezoelectric layer 14 are viewed along a laminating direction from a direction corresponding to a down direction in FIG. 2. It should be noted that, in FIG. 2, for example, the piezoelectric layer 14 side is an upper side of the support substrate 16 and the piezoelectric layer 14.

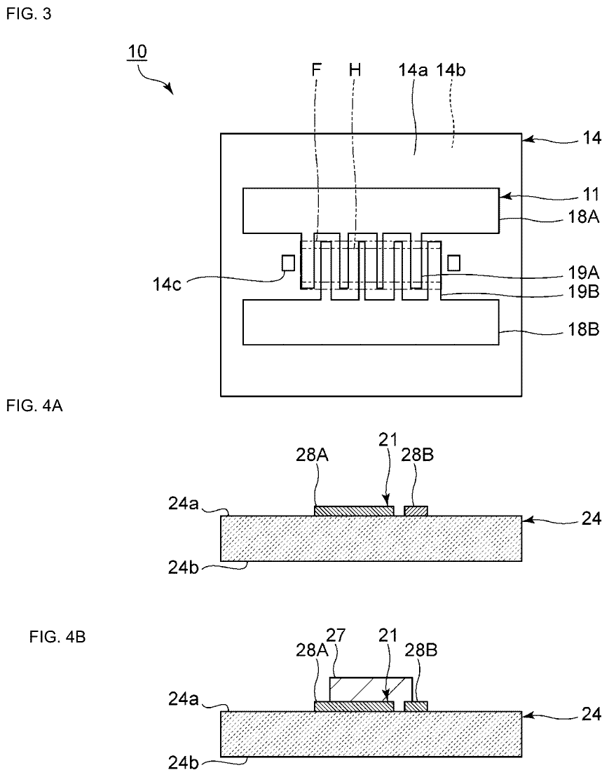

FIG. 3 is a schematic bottom view showing a configuration of the IDT provided on the first main surface of the piezoelectric layer according to the first example embodiment.

The IDT 11 includes a pair of busbar portions and a plurality of electrode finger portions. Specifically, the pair of busbar portions are a first busbar portion 18A and a second busbar portion 18B. The first busbar portion 18A and the second busbar portion 18B oppose each other. The plurality of electrode finger portions are, specifically, a plurality of first electrode finger portions 19A and a plurality of second electrode finger portions 19B. One end of each of the plurality of first electrode finger portions 19A is connected to the first busbar portion 18A. One end of each of the plurality of second electrode finger portions 19B is connected to the second busbar portion 18B. The plurality of first electrode finger portions 19A and the plurality of second electrode finger portions 19B are interdigitated between each other.

Hereinafter, a direction in which the plurality of electrode finger portions extend will be referred to as an electrode finger portion extending direction, and a direction in which the electrode finger portions adjacent to each other oppose each other will be referred to as an electrode finger portion opposing direction. In the present example embodiment, the electrode finger portion extending direction and the electrode finger portion opposing direction are orthogonal to each other.

In the present example embodiment, each busbar portion includes at least one metal layer. Each electrode finger portion is an electrode finger made of at least one metal layer. More specifically, the first busbar portion 18A and the second busbar portion 18B first busbar are the and the second busbar, respectively. The plurality of first electrode finger portions 19A and the plurality of second electrode finger portions 19B are a plurality of first electrode fingers and a plurality of second electrode fingers. That is, the IDT 11 includes at least one metal layer.

However, each busbar portion may be a multilayer body including the busbar and a dielectric layer. Each electrode finger portion may be a multilayer body including the electrode finger and the dielectric layer. In this case, the IDT 11 is made of a multilayer body including the metal layer and the dielectric layer.

In the IDT 11, the plurality of electrode finger portions need only be located in the cavity portion 12a. In the present example embodiment, the insulating layer 15 shown in FIG. 2 is laminated on a portion of each busbar portion. The other portion of each busbar portion is located in the cavity portion 12a.

As shown in FIG. 1, a plurality of through holes 14c are provided in the membrane portion 14d of the piezoelectric layer 14. More specifically, in the present example embodiment, a pair of through holes 14c are provided in the piezoelectric layer 14. Each through hole 14c reaches the cavity portion 12a. The pair of through holes 14c are disposed to interpose the IDT 11 in the electrode finger portion opposing direction. It should be noted that the piezoelectric layer 14 need only be provided with at least one through hole 14c.

The through hole 14c is used to remove a sacrificial layer by performing etching in a case of forming the cavity portion 12a. Therefore, the through hole 14c is an etching hole.

In the present example embodiment, a plurality of via holes 14e are preferably provided in the membrane portion 14d of the piezoelectric layer 14. More specifically, a pair of via holes 14e are provided in the piezoelectric layer 14. One via hole 14e of the pair of via holes 14e reaches the first busbar portion 18A. A first wiring electrode 25A is provided continuously in the via hole 14e of the piezoelectric layer 14 and on the second main surface 14b. The first wiring electrode 25A is connected to the first busbar portion 18A. The other via hole 14e reaches the second busbar portion 18B. A second wiring electrode 25B is continuously provided in the via hole 14e and the second main surface 14b. The second wiring electrode 25B is connected to the second busbar portion 18B.

A portion of the first wiring electrode 25A provided on the second main surface 14b of the piezoelectric layer 14 is connected to a first terminal electrode 26A. More specifically, the first terminal electrode 26A is provided on the first wiring electrode 25A. A portion of the second wiring electrode 25B provided on the second main surface 14b is connected to a second terminal electrode 26B. More specifically, the second terminal electrode 26B is provided on the second wiring electrode 25B. The acoustic wave device 10 is electrically connected to other elements or the like through the first terminal electrode 26A and the second terminal electrode 26B.

A feature of the present example embodiment is that, as shown in FIG. 2, the electrode finger portion at a position closer to the through hole 14c in the plurality of electrode finger portions has a smaller thickness and a larger width. In an example embodiment of the present invention, the following dimensional relationship need only be provided in at least one set of the electrode finger portions. The dimensional relationship is a relationship in which at least a portion of the electrode finger portion at a position closer to the through hole 14c in one set of the electrode finger portions has a smaller thickness and a larger width than at least a portion of the electrode finger portion at a position farther from the through hole 14c. One set of the electrode finger portions may be a set of the first electrode finger portions 19A, a set of the second electrode finger portions 19B, or a set of the first electrode finger portion 19A and the second electrode finger portion 19B.

With the acoustic wave device 10 having the above-described configuration, a cross-sectional area of the electrode finger portion in the IDT 11 can be a constant or substantially constant value, and the electrical characteristics of the acoustic wave device 10 can be stabilized. The detailed description will be made below together with an example of a manufacturing method of the acoustic wave device 10 according to the present example embodiment.

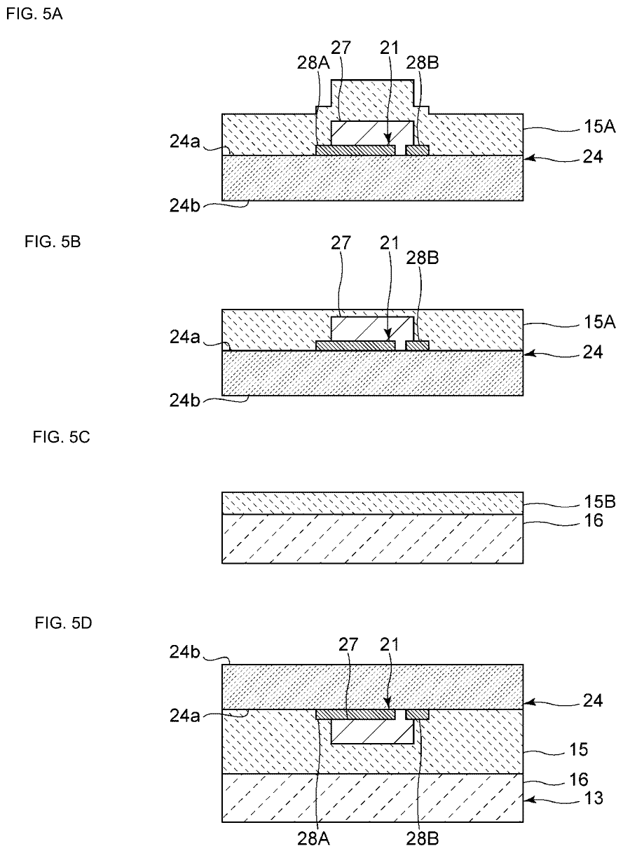

FIGS. 4A and 4B are schematic cross-sectional views taken along the electrode finger portion extending direction and showing an IDT electrode forming step and a sacrificial layer forming step in an example of the manufacturing method of the acoustic wave device according to the first example embodiment of the present invention. FIGS. 5A to 5D are schematic cross-sectional views taken along the electrode finger portion extending direction and showing a first insulating layer forming step, a first insulating layer flattening step, a second insulating layer forming step, and a piezoelectric substrate bonding step in the example of the manufacturing method of the acoustic wave device according to the first example embodiment of the present invention.

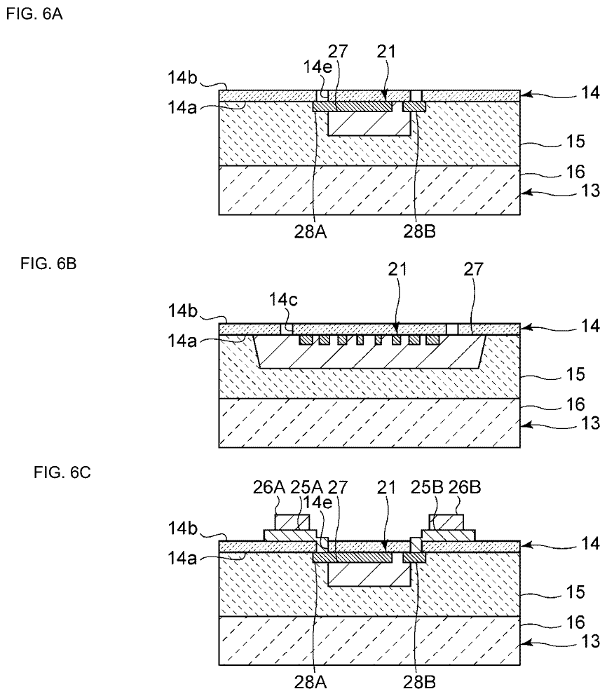

FIG. 6A is a schematic cross-sectional view taken along the electrode finger portion extending direction and showing a piezoelectric layer grinding step and a via hole forming step in the example of the manufacturing method of the acoustic wave device according to the first example embodiment. FIG. 6B is a schematic elevational cross-sectional view showing a through hole forming step in the example of the manufacturing method of the acoustic wave device according to the first example embodiment. FIG. 6C is a schematic cross-sectional view taken along the electrode finger portion extending direction and showing a wiring electrode forming step and a terminal electrode forming step in the example of the manufacturing method of the acoustic wave device according to the first example embodiment.

As shown in FIG. 4A, a piezoelectric substrate 24 is prepared. The piezoelectric substrate 24 is included in the piezoelectric layer according to the present example embodiment. The piezoelectric substrate 24 includes a third main surface 24a and a fourth main surface 24b. The third main surface 24a and the fourth main surface 24b oppose each other. An IDT electrode 21 is provided on the third main surface 24a of the piezoelectric substrate 24. The IDT electrode 21 can be formed by, for example, a lift-off method using a sputtering method or a vacuum deposition method.

The IDT electrode 21 includes the pair of busbars and the plurality of electrode fingers. Specifically, the pair of busbars are a first busbar 28A and a second busbar 28B. The thicknesses of the plurality of electrode fingers are preferably the same or substantially the same as each other. On the other hand, the widths of the electrode fingers adjacent each other are not the same as each other. More specifically, in the step described below, the piezoelectric substrate 24 is the piezoelectric layer 14 shown in FIG. 2, and the through hole 14c is provided in the piezoelectric layer 14. The electrode finger closer to a portion in which the through hole 14c is provided has a larger width. In at least one set of the electrode fingers, the width of the electrode finger closer to the portion in which the through hole 14c is provided need only be larger than the width of the electrode finger farther from the portion.

Next, as shown in FIG. 4B, a sacrificial layer 27 is provided on the third main surface 24a of the piezoelectric substrate 24. The sacrificial layer 27 is provided to cover at least a portion of the first busbar 28A and the second busbar 28B of the IDT electrode 21, and the plurality of electrode fingers. As the material of the sacrificial layer 27, for example, Zno, SiO₂, Cu, a resin, or the like can be used.

Next, as shown in FIG. 5A, a first insulating layer 15A is preferably provided on the third main surface 24a of the piezoelectric substrate 24. More specifically, the first insulating layer 15A is provided to cover the IDT electrode 21 and the sacrificial layer 27. The first insulating layer 15A can be formed by, for example, a sputtering method or a vacuum deposition method. Then, as shown in FIG. 5B, the first insulating layer 15A is flattened. In a case of flattening the first insulating layer 15A, for example, a grind, a chemical mechanical polishing (CMP) method, or the like need only be used.

On the other hand, as shown in FIG. 5C, a second insulating layer 15B is provided on one main surface of the support substrate 16. Then, the first insulating layer 15A shown in FIG. 5B and the second insulating layer 15B shown in FIG. 5C are bonded to each other. As a result, as shown in FIG. 5D, the insulating layer 15 is formed, and the support substrate 16 and the piezoelectric substrate 24 are bonded to each other.

Next, the thickness of the piezoelectric substrate 24 is adjusted. More specifically, the thickness of the piezoelectric substrate 24 is reduced by, for example, grinding or polishing the fourth main surface 24b side of the piezoelectric substrate 24. For example, grinding, a CMP method, an ion slicing method, or etching can be used for the adjustment of the thickness of the piezoelectric substrate 24. As a result, as shown in FIG. 6A, the piezoelectric layer 14 is obtained. The first main surface 14a of the piezoelectric layer 14 corresponds to the third main surface 24a of the piezoelectric substrate 24. The second main surface 14b of the piezoelectric layer 14 corresponds to the fourth main surface 24b of the piezoelectric substrate 24.

Next, the plurality of via holes 14e are provided in the piezoelectric layer 14 so as to extend to each of the first busbar 28A and the second busbar 28B. Simultaneously, as shown in FIG. 6B, the plurality of through holes 14c are provided in the piezoelectric layer 14 so as to reach the sacrificial layer 27. The through hole 14c and the via hole 14e can be formed by, for example, a reactive ion etching (RIE) method.

Next, as shown in FIG. 6C, the first wiring electrode 25A is continuously provided in one via hole 14e of the piezoelectric layer 14 and on the second main surface 14b. Accordingly, the first wiring electrode 25A is connected to the first busbar 28A. Further, the second wiring electrode 25B is continuously provided in the other via hole 14e and on the second main surface 14b. Accordingly, the second wiring electrode 25B is connected to the second busbar 28B. The first wiring electrode 25A and the second wiring electrode 25B can be formed by, for example, a lift-off method using a sputtering method or a vacuum deposition method.

Next, the first terminal electrode 26A is provided on a portion of the first wiring electrode 25A provided on the second main surface 14b of the piezoelectric layer 14. Further, the second terminal electrode 26B is provided on a portion of the second wiring electrode 25B provided on the second main surface 14b of the piezoelectric layer 14. The first terminal electrode 26A and the second terminal electrode 26B can be formed by, for example, a lift-off method using a sputtering method or a vacuum deposition method.

Next, the sacrificial layer 27 is removed by using the through hole 14c shown in FIG. 6B. More specifically, the sacrificial layer 27 in the recess portion of the insulating layer 15 is removed by allowing an etching solution to flow in from the through hole 14c. In this case, each electrode finger of the IDT electrode 21 is also etched. As a result, the IDT 11 and the cavity portion 12a shown in FIG. 2 are formed. In this way, the acoustic wave device 10 is obtained.

More specifically, the amount removed by the etching is larger as the electrode finger is closer to the through hole 14c of the piezoelectric layer 14. Therefore, a change in the thickness due to the etching is larger as the electrode finger is closer to the through hole 14c. On the other hand, a change in the width of the electrode finger due to the etching is small regardless of the position of the electrode finger. Therefore, in a case of manufacturing the acoustic wave device 10, before the etching, the electrode finger at a position closer to the through hole 14c need only have a larger width, and the thicknesses of the plurality of electrode fingers need only be made constant or substantially constant regardless of the position, for example. As a result, the thickness of the electrode finger portion at a position closer to the through hole 14c of the piezoelectric layer 14, which is formed by performing the etching, is smaller. It should be noted that, in the electrode finger portion, a state in which the width is large is maintained.

On the other hand, the amount removed by the etching is smaller as the electrode finger is located at a position farther from the through hole 14c. Therefore, the thickness of the electrode finger portion at a position farther from the through hole 14c, which is formed by performing the etching, is larger. The width of the electrode finger portion is small. Therefore, the cross-sectional area of each electrode finger portion can be made close to a constant value, and the mass of each electrode finger portion can be made close to a constant value. As a result, the mass added to the piezoelectric layer 14 by each electrode finger portion is made close to a constant value. Therefore, the electrical characteristics of the acoustic wave device 10 can be stabilized.

Hereinafter, the further detailed description of the configuration of the present example embodiment will be provided.

In the acoustic wave device 10 shown in FIG. 2, in a case where a thickness of the piezoelectric layer 14 is d and a center-to-center distance between the adjacent electrode finger portions is p, d/p is about 0.5 or less. As a result, the bulk wave in the thickness shear mode is suitably excited.

As shown in FIG. 3, a region in which the electrode finger portions adjacent to each other overlap each other when viewed from the electrode finger portion opposing direction is a cross region F. In the acoustic wave device using the bulk wave in the thickness shear mode, the cross region F includes a plurality of excitation regions. Specifically, a region, which is a region in which the adjacent electrode finger portions overlap each other when viewed from the electrode finger portion opposing direction and a region between the centers of the electrode fingers adjacent each other, is the excitation region. On the other hand, in a case where the acoustic wave device 10 is configured to use the plate wave, the excitation region is the cross region F.

In the present example embodiment, the plurality of through holes 14c are provided. In this case, it is preferable that the dimensional relationship described above is provided for each through hole 14c. The dimensional relationship is a dimensional relationship in which at least a portion of the electrode finger portion at a position closer to the through hole 14c in one set of the electrode finger portions has a smaller thickness and a larger width than at least a portion of the electrode finger portion at a position farther from the through hole 14c. It is preferable that the one set of the electrode finger portions in which the dimensional relationship is established includes the electrode fingers connected to each other at different potentials.

A portion of, for example, about 80% of a center of the cross region F in the electrode finger portion extending direction is a center portion H. It is preferable that the dimensional relationship is a dimensional relationship between all of the portions of one set of the electrode finger portions located at the center portion H. In this case, the electrical characteristics of the acoustic wave device 10 can be more reliably stabilized, and a Q value can be increased. It is more preferable that the dimensional relationship is a dimensional relationship between all of the portions of one set of the electrode finger portions located in the cross region F. In this case, the electrical characteristics of the acoustic wave device 10 can be more reliably stabilized.

A difference in the thickness in the dimensional relationship is not particularly limited, but is preferably, for example, about 10 nm or more. The thickness of the electrode finger portion may be, for example, an average thickness of the cross section which is the comparison target.

The acoustic wave device 10 according to the present example embodiment is preferably one acoustic wave resonator. However, the acoustic wave device according to the present invention may include, for example, two or more acoustic wave resonators. A plurality of IDTs each corresponding to the IDT 11 shown in FIG. 2 may be provided in the same cavity portion 12a. In this case, in the plurality of electrode finger portions of the plurality of IDTs, a distance relationship with the same through hole 14c is provided. In the plurality of electrode finger portions of the plurality of IDTs, the dimensional relationship described above may be provided for the through hole 14c. For example, the dimensional relationship described above may be provided between the electrode finger portion of one IDT and the electrode finger portion of the other IDT. Alternatively, as in the present example embodiment, the dimensional relationship described above may be provided in the plurality of electrode finger portions of one IDT. The acoustic wave device according to the present invention need only include at least one IDT. The dimensional relationship described above need only be provided in the plurality of electrode finger portions of at least one IDT.

In a case where the acoustic wave device according to the present example embodiment of the present invention includes a plurality of acoustic wave resonators, and each acoustic wave resonator is configured to use the bulk wave in the thickness shear mode, the acoustic wave device is configured to use the bulk wave in the thickness shear mode. d/p is a numerical value in each IDT. In a case where each acoustic wave resonator is configured to use the plate wave, the acoustic wave device is configured to use the plate wave.

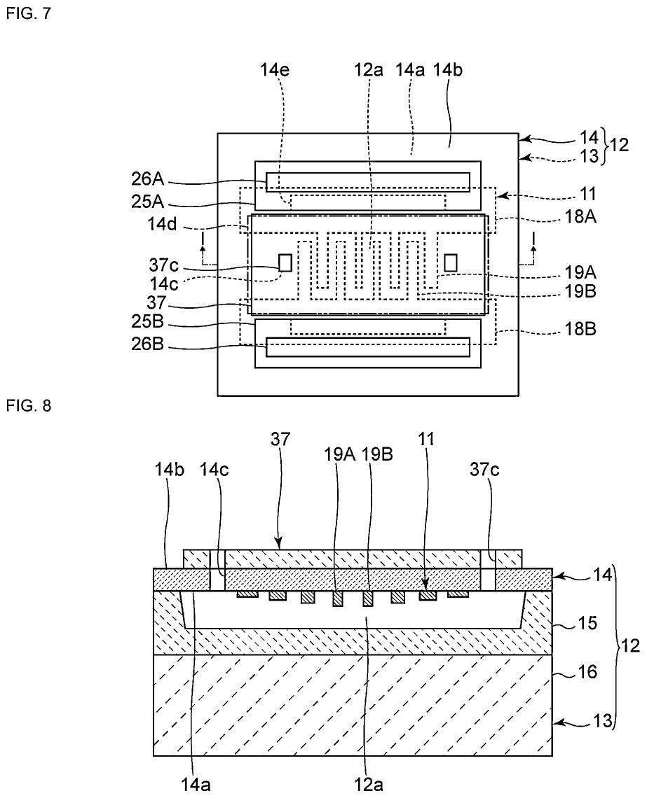

FIG. 7 is a schematic plan view of an acoustic wave device according to a second example embodiment of the present invention. FIG. 8 is a schematic cross-sectional view taken along line I-I in FIG. 7.

As shown in FIGS. 7 and 8, the present example embodiment is different from the first example embodiment in that a frequency adjustment film 37 is provided on the second main surface 14b of the piezoelectric layer 14 so as to overlap the IDT 11 in plan view. Except for the above points, the acoustic wave device according to the present example embodiment preferably has the same or substantially the same configuration as the acoustic wave device 10 according to the first example embodiment.

A plurality of through holes 37c are provided in the frequency adjustment film 37. The through hole 37c of the frequency adjustment film 37 communicates with the through hole 14c of the piezoelectric layer 14. However, the through hole 37c need not always be provided in the frequency adjustment film 37.

The frequency of the acoustic wave device can be easily adjusted by adjusting the thickness of the frequency adjustment film 37. As the material of the frequency adjustment film 37, for example, silicon oxide, silicon nitride, silicon oxynitride, or the like can be used.

Also in the present example embodiment, as shown in FIG. 8, the electrode finger portion at a position closer to the through hole 14c of the piezoelectric layer 14 in the plurality of electrode finger portions has a smaller thickness and a larger width. Therefore, the cross-sectional area of the electrode finger portion in the IDT 11 can be made close to a constant value, and the electrical characteristics of the acoustic wave device can be stabilized.

The configuration in which the frequency adjustment film 37 is provided can also be used in an example embodiment according to the present invention other than the second example embodiment.

Hereinafter, an example of a manufacturing method of the acoustic wave device according to the present example embodiment will be described.

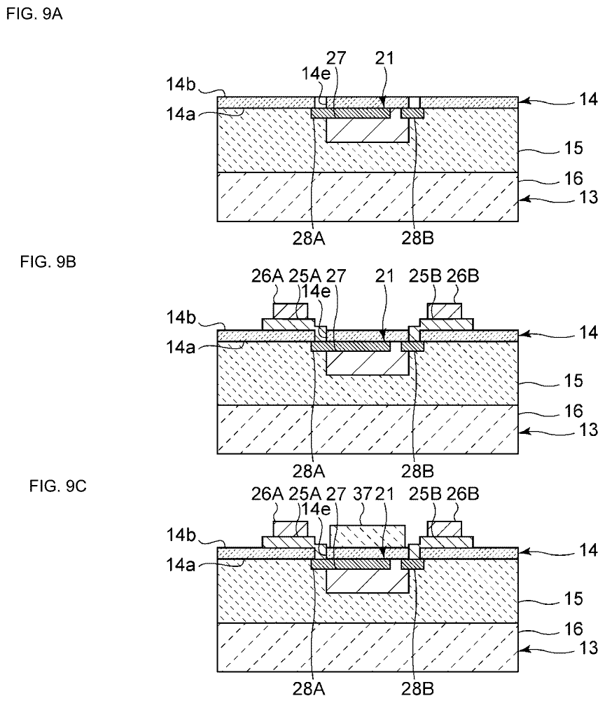

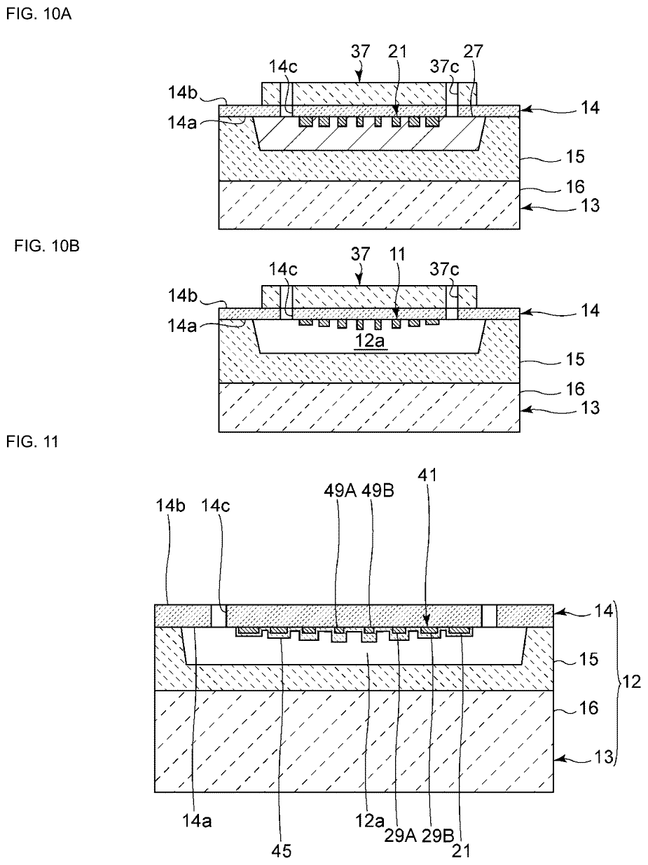

FIGS. 9A to 9C are schematic cross-sectional views taken along an electrode finger portion extending direction and showing a via hole forming step, a wiring electrode forming step, a terminal electrode forming step, and a frequency adjustment film forming step in an example of the manufacturing method of the acoustic wave device according to the second example embodiment. FIGS. 10A and 10B are schematic elevational cross-sectional views showing a through hole forming step, a sacrificial layer removal step, and an IDT forming step in the example of the manufacturing method of the acoustic wave device according to the second example embodiment.

The steps up to the piezoelectric layer grinding step of obtaining the piezoelectric layer 14 shown in FIG. 9A can preferably be performed in the same or substantially the same manner as in the example of the manufacturing method of the acoustic wave device 10 according to the first example embodiment described above. Next, the plurality of via holes 14e are provided in the piezoelectric layer 14 so as to extend to each of the first busbar 28A and the second busbar 28B. In this case, unlike the example of the manufacturing method of the acoustic wave device 10 according to the first example embodiment, the plurality of through holes 14c shown in FIG. 6B are not provided.

Next, as shown in FIG. 9B, the first wiring electrode 25A is continuously provided in one via hole 14e of the piezoelectric layer 14 and on the second main surface 14b. Accordingly, the first wiring electrode 25A is connected to the first busbar 28A. Further, the second wiring electrode 25B is continuously provided in the other via hole 14e and on the second main surface 14b. Accordingly, the second wiring electrode 25B is connected to the second busbar 28B.

Next, the first terminal electrode 26A is provided on a portion of the first wiring electrode 25A provided on the second main surface 14b of the piezoelectric layer 14. Further, the second terminal electrode 26B is provided on a portion of the second wiring electrode 25B provided on the second main surface 14b of the piezoelectric layer 14.

Next, as shown in FIG. 9C, the frequency adjustment film 37 is provided on the second main surface 14b of the piezoelectric layer 14. The frequency adjustment film 37 is provided to overlap at least a portion of the IDT electrode 21 in plan view. The frequency adjustment film 37 can be formed by, for example, a sputtering method or a vacuum deposition method.

Next, as shown in FIG. 10A, the plurality of through holes 14c are provided in the piezoelectric layer 14 so as to reach the sacrificial layer 27. In this case, the plurality of through holes 37c are also provided in the frequency adjustment film 37 so as to communicate with the respective plurality of through holes 14c The through hole 14c of the piezoelectric layer 14 and the through hole 37c of the frequency adjustment film 37 can be formed by, for example, an RIE method.

Next, the sacrificial layer 27 is removed by using the through hole 14c of the piezoelectric layer 14 and the through hole 37c of the frequency adjustment film 37. More specifically, the sacrificial layer 27 in the recess portion of the insulating layer 15 is removed by allowing the etching solution to flow in from the through hole 14c and the through hole 37c. In this case, each electrode finger of the IDT electrode 21 is also etched. As a result, the IDT 11 and the cavity portion 12a shown in FIG. 10B are formed.

Next, the frequency adjustment film 37 is trimmed to adjust the thickness of the frequency adjustment film 37. As a result, the frequency of the acoustic wave device is adjusted. In this way, the acoustic wave device according to the second example embodiment shown in FIG. 8 is obtained.

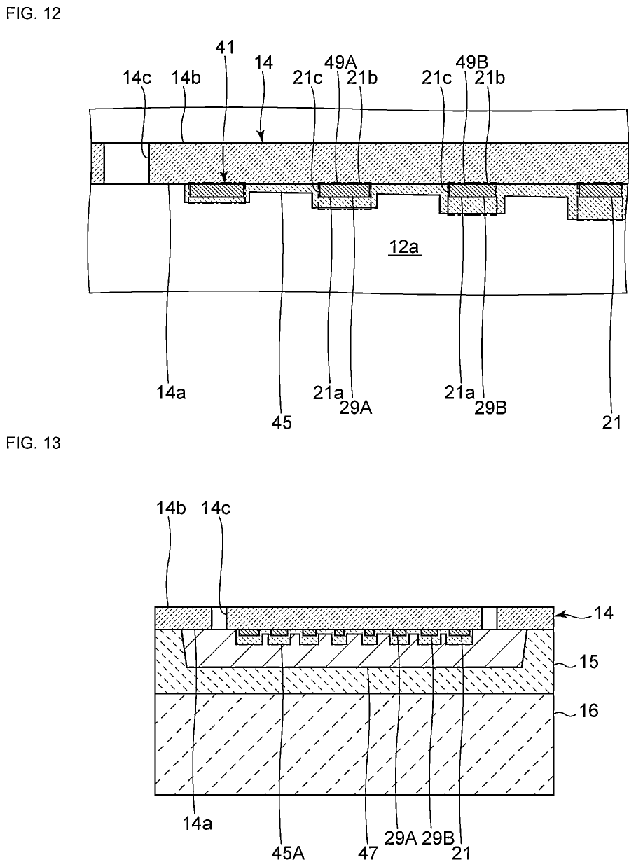

FIG. 11 is a schematic elevational cross-sectional view of an acoustic wave device according to a third example embodiment. FIG. 12 is a schematic elevational cross-sectional view showing a vicinity of a portion of an IDT of the acoustic wave device according to the third example embodiment, in an enlarged manner. In FIG. 12, each electrode finger portion is surrounded by a one-dot chain line.

As shown in FIGS. 11 and 12, the present example embodiment is different from the first example embodiment in that a dielectric layer 45 is provided on the first main surface 14a of the piezoelectric layer 14. The present example embodiment is different from the first example embodiment also in that an IDT 41 is a multilayer body including the IDT electrode 21 and the dielectric layer 45. Except for the above points, the acoustic wave device according to the present example embodiment has the same or substantially the same configuration as the acoustic wave device 10 according to the first example embodiment.

Each of a plurality of electrode finger portions of the IDT 41 is a multilayer body including an electrode finger and the dielectric layer 45. More specifically, a first electrode finger portion 49A of the IDT 41 is a multilayer body including a first electrode finger 29A of the IDT electrode 21 and the dielectric layer 45. A second electrode finger portion 49B of the IDT 41 is a multilayer body including a second electrode finger 29B of the IDT electrode 21 and the dielectric layer 45.

In the IDT electrode 21, the thicknesses of the plurality of electrode fingers are the same or substantially the same as each other. On the other hand, the widths of the electrode fingers adjacent each other are not the same as each other. More specifically, the electrode finger closer to the through hole 14c of the piezoelectric layer 14 has a larger width. In at least one set of the electrode fingers, the width of the electrode finger closer to the through hole 14c need only be larger than the width of the electrode finger farther from the through hole 14c. In the present example embodiment, in the dielectric layer 45, in a plurality of portions forming the plurality of electrode finger portions, a portion closer to the through hole 14c has a smaller thickness. However, among the portions of the dielectric layer 45 forming at least one set of the electrode finger portions, the thickness of the portion closer to the through hole 14c need only be smaller than the thickness of the portion farther from the through hole 14c.

The dielectric layer 45 is provided on the first main surface 14a of the piezoelectric layer 14 so as to cover the IDT electrode 21. Therefore, in a portion in which the electrode finger and the dielectric layer 45 are laminated, the piezoelectric layer 14, the electrode finger, and the dielectric layer 45 are laminated in this order.

As shown in FIG. 12, each electrode finger of the IDT electrode 21 preferably includes a first surface 21a, a second surface 21b, and a side surface 21c. The first surface 21a and the second surface 21b oppose each other in a thickness direction of the electrode finger. Out of the first surface 21a and the second surface 21b, the second surface 21b is a surface on the piezoelectric layer 14 side. The side surface 21c is connected to the first surface 21a and the second surface 21b.

The dielectric layer 45 is also provided in a portion of the piezoelectric layer 14 located between the electrode fingers. Therefore, the dielectric layer 45 covers the side surface 21c of each electrode finger. Of course, in the present example embodiment, as shown by being surrounded by one-dot chain line in FIG. 12, a portion of the dielectric layer 45 forming the electrode finger portion is a portion in the dielectric layer 45 that overlaps the electrode finger in plan view. Therefore, the portion of the dielectric layer 45 that covers the side surface 21c of the electrode finger is not included in the electrode finger portion.

The thickness of the electrode finger portion is a total thickness of the portion of the electrode finger and the portion of the dielectric layer. On the other hand, the width of the electrode finger portion is the same or substantially the same as the width of the electrode finger. Therefore, in the IDT 41, in a case of calculating a duty ratio or a metallization ratio, the width of the electrode finger in each electrode finger portion need only be used.

Also in the present example embodiment, the electrode finger portion at a position closer to the through hole 14c of the piezoelectric layer 14 in the plurality of electrode finger portions has a smaller thickness and a larger width. It should be noted that, in the present example embodiment, the thickness of the electrode finger in the electrode finger portion is constant regardless of the position. On the other hand, in one set of the electrode finger portions, the thickness of the portion of the dielectric layer 45 in the electrode finger portion at a position closer to the through hole 14c is smaller than the thickness of the portion of the dielectric layer 45 in the electrode finger portion at a position farther from the through hole 14c. With the acoustic wave device according to the present example embodiment having the above-described configuration, the cross-sectional area of the electrode finger portion in the IDT 41 can be made to be close to a constant value. As a result, the electrical characteristics of the acoustic wave device can be stabilized.

In addition, since each electrode finger is protected by the dielectric layer 45, the IDT 41 is unlikely to be damaged. As the material of the dielectric layer 45, for example, silicon oxide, silicon nitride, silicon oxynitride, or the like can be used. For example, in a case where silicon oxide is used in the dielectric layer 45, an absolute value of a temperature coefficient of frequency (TCF) in the acoustic wave device can be reduced, and the temperature characteristics of frequency can be improved.

The thickness of the dielectric layer 45 is not particularly limited, but is, for example, preferably about 0.5 times or less of the thickness of the electrode finger.

In order to obtain the acoustic wave device according to the present example embodiment, for example, as shown in FIG. 4A, the dielectric layer preferably need only be formed on the third main surface 24a of the piezoelectric substrate 24 so as to cover the IDT electrode 21 after the IDT electrode 21 is formed. The dielectric layer can be formed by, for example, a sputtering method or a vacuum deposition method. The sacrificial layer 27 shown in FIG. 4B need only be formed after the dielectric layer is formed. The subsequent steps can be performed in the same or substantially the same manner as in the example of the manufacturing method of the acoustic wave device 10 according to the first example embodiment.

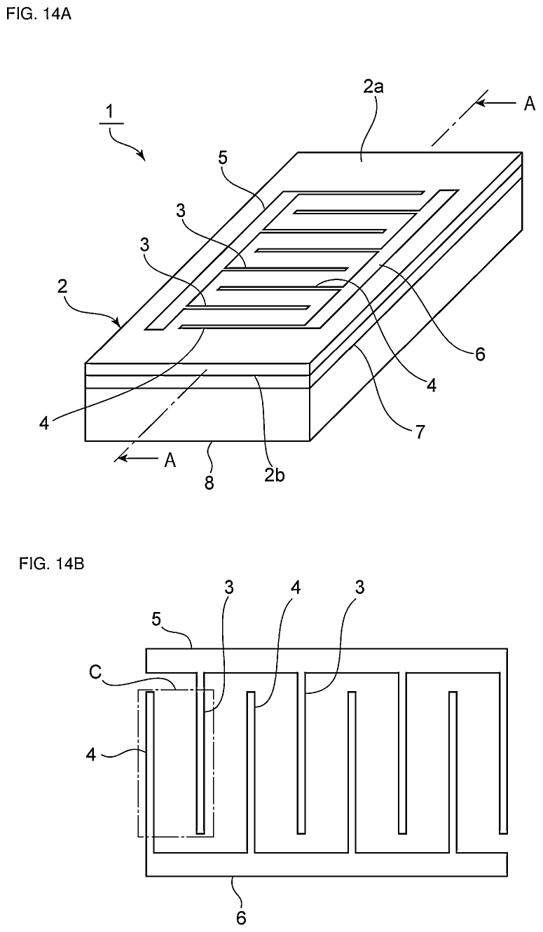

More specifically, in the step of removing the sacrificial layer 27, as shown in FIG. 13, the electrode finger of the IDT electrode 21 is covered by the dielectric layer 45A. Therefore, even in the step of removing the sacrificial layer 27, the IDT electrode 21 is not removed by etching. Therefore, the thickness and the width of each electrode finger of the IDT electrode 21 are not changed even in a case where the etching is performed.

Meanwhile, in the step of removing the sacrificial layer 27, the dielectric layer 45A is etched. The amount removed by the etching is larger as a portion of the dielectric layer 45A is closer to the through hole 14c of the piezoelectric layer 14. Therefore, a change in thickness due to etching is larger in a portion of the dielectric layer 45A closer to the through hole 14c. On the other hand, the amount removed by the etching is smaller as a portion of the dielectric layer 45A is farther from the through hole 14c. Therefore, the change in thickness due to the etching is smaller as a portion of the dielectric layer 45A is farther from the through hole 14c. Therefore, in a case of manufacturing the acoustic wave device according to the present example embodiment, the thickness of the portion of the dielectric layer 45A laminated on the electrode finger need only be made constant or substantially constant regardless of the position, for example.

As shown in FIG. 12, in the present example embodiment, the thickness of the portion of the dielectric layer 45 located between the electrode fingers is preferably not constant. More specifically, the thickness of the portion of the dielectric layer 45 located between the electrode fingers is larger as the portion is farther from the through hole 14c of the piezoelectric layer 14. However, the present invention is not limited thereto.

Hereinafter, the thickness shear mode will be described in detail with reference to an example of the acoustic wave device in which the IDT is the IDT electrode and the thicknesses of the plurality of electrode finger portions are constant or substantially constant. In the following example, the IDT electrode is provided on the main surface corresponding to the second main surface 14b of the piezoelectric layer 14 shown in FIG. 2 and the like. However, the bulk wave in the thickness shear mode is not particularly affected depending on which main surface of the piezoelectric layer the IDT electrode is provided on. The “electrode” in the IDT electrode described below corresponds to an electrode finger and an electrode finger portion according to the present invention. The support portion in the following example corresponds to a support substrate.

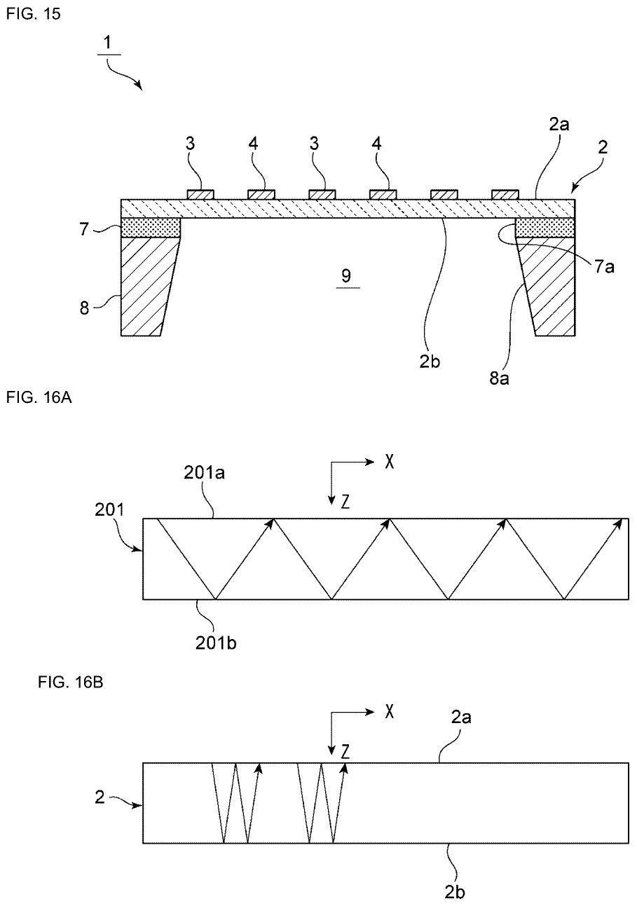

FIG. 14A is a schematic perspective view showing an appearance of the acoustic wave device using the bulk wave in the thickness shear mode, and FIG. 14B is a plan view showing the electrode structure on the piezoelectric layer, and FIG. 15 is a cross-sectional view of a portion taken along line A-A in FIG. 14A.

An acoustic wave device 1 preferably includes a piezoelectric layer 2 made of LiNbO₃, for example. The piezoelectric layer 2 may be made of LiTaO₃, for example. A cut-angle of LiNbO₃ or LiTaO₃ is a Z cut, but may be a rotation Y cut or an X cut. The thickness of the piezoelectric layer 2 is not particularly limited, but is, for example, preferably about 40 nm or more and about 1000 nm or less, and more preferably about 50 nm or more and about 1000 nm or less in order to effectively excite the thickness shear mode. The piezoelectric layer 2 includes first and second main surfaces 2a and 2b opposing each other. Electrodes 3 and 4 are provided on the first main surface 2a. Here, the electrode 3 is an example of a “first electrode” and the electrode 4 is an example of a “second electrode”. In FIGS. 14A and 14B, a plurality of the electrodes 3 are connected to a first busbar 5. A plurality of electrodes 4 are connected to a second busbar 6. The plurality of electrodes 3 and the plurality of electrodes 4 are interdigitated between each other. Each of the electrodes 3 and 4 has a rectangular or substantially rectangular shape and a length direction. The electrode 3 and the electrode 4 adjacent thereto oppose each other in a direction orthogonal or substantially orthogonal to the length direction. Both the length direction of the electrodes 3 and 4 and the direction orthogonal or substantially orthogonal to the length direction of the electrodes 3 and 4 are directions crossing a thickness direction of the piezoelectric layer 2. Therefore, it can be said that the electrode 3 and the electrode 4 adjacent thereto oppose each other in the direction crossing the thickness direction of the piezoelectric layer 2. In addition, the length direction of the electrodes 3 and 4 may be changed to the direction orthogonal or substantially orthogonal to the length direction of the electrodes 3 and 4 shown in FIGS. 14A and 14B. That is, in FIGS. 14A and 14B, the electrodes 3 and 4 may extend in the direction in which the first busbar 5 and the second busbar 6 extend. In this case, the first busbar 5 and the second busbar 6 extend in the direction in which the electrodes 3 and 4 extend in FIGS. 14A and 14B. A plurality of pairs of structures in which the electrode 3 connected to one potential and the electrode 4 connected to the other potential are adjacent to each other are provided in a direction orthogonal to the length direction of the electrodes 3 and 4. Here, a case where the electrodes 3 and 4 are adjacent to each other does not mean a case where the electrodes 3 and 4 are disposed to be in direct contact with each other, but mean a case where the electrodes 3 and 4 are disposed with a gap therebetween. In a case where the electrodes 3 and 4 are adjacent to each other, the electrodes connected to a hot electrode or a ground electrode, including the other electrodes 3 and 4, are not disposed between the electrodes 3 and 4. The number of pairs does not have to be integer pairs, but may be 1.5 pairs, 2.5 pairs, or the like. The center-to-center distance, that is, the pitch between the electrodes 3 and 4 is, for example, preferably in a range of about 1 μm or more and about 10 μm or less. The widths of the electrodes 3 and 4, that is, the dimensions of the electrodes 3 and 4 in the opposing direction are, for example, preferably in a range of about 50 nm or more and about 1000 nm or less, and more preferably in a range of about 150 nm or more and about 1000 nm or less. The center-to-center distance between the electrodes 3 and 4 is a distance connecting the center of the dimension (width dimension) of the electrode 3 in the direction orthogonal or substantially orthogonal to the length direction of the electrode 3 and the center of the dimension (width dimension) of the electrode 4 in the direction orthogonal or substantially orthogonal to the length direction of the electrode 4.

In the acoustic wave device 1, since the Z-cut piezoelectric layer is used, the direction orthogonal or substantially orthogonal to the length direction of the electrodes 3 and 4 is a direction orthogonal or substantially orthogonal to a polarization direction of the piezoelectric layer 2. This shall not be applied to case where a piezoelectric material with a different cut-angle is used as the piezoelectric layer 2. Here, “orthogonal” is not limited to being strictly orthogonal, but may be substantially orthogonal (angle between the direction orthogonal to the length direction of the electrodes 3 and 4 and the polarization direction is, for example, in a range of about 90°±10°.

A support portion 8 is preferably laminated on the second main surface 2b side of the piezoelectric layer 2 with an insulating layer 7 interposed therebetween. The insulating layer 7 and the support portion 8 have a frame shape and includes through holes 7a and 8a as shown in FIG. 15. As a result, a cavity portion 9 is formed. The cavity portion 9 is provided not to disturb the vibration of the excitation region C of the piezoelectric layer 2. Therefore, the support portion 8 is laminated on the second main surface 2b with the insulating layer 7 interposed therebetween at a position not overlapping the portion in which at least the pair of electrodes 3 and 4 is provided. It should be noted that the insulating layer 7 does not have to be provided. Therefore, the support portion 8 can be directly or indirectly laminated on the second main surface 2b of the piezoelectric layer 2.

The insulating layer 7 is preferably made of silicon oxide, for example. However, in addition to silicon oxide, an appropriate insulating material such as, for example, silicon oxynitride or alumina can be used. The support portion 8 is preferably made of Si, for example. A plane orientation of the plane of Si on the piezoelectric layer 2 side may be (100), (110), or (111). Si that forms the support portion 8 is preferably high resistance having a resistivity of, for example, about 4 kQcm or However, the support portion 8 can also be made of an more, appropriate insulating material or semiconductor material.

Examples of the material of the support portion 8 include piezoelectric materials such as aluminum oxide, lithium tantalate, lithium niobate, and quartz crystal, various ceramics such as alumina, magnesia, sapphire, silicon nitride, aluminum nitride, silicon carbide, zirconia, cordierite, mullite, steatite, and forsterite, dielectrics such as diamond and glass, and semiconductors such as gallium nitride.

The plurality of electrodes 3 and 4 and the first and second busbars 5 and 6 are made of appropriate metals or alloys such as, for example, Al and AlCu alloys. In the acoustic wave device 1, the electrodes 3 and 4 and the first and second busbars 5 and 6 have a structure in which an Al film is laminated on a Ti film. A close contact layer other than the Ti film may be used.

During driving, the AC voltage is applied between the plurality of electrodes 3 and the plurality of electrodes 4. More specifically, the AC voltage is applied between the first busbar 5 and the second busbar 6. As a result, it is possible to obtain the resonance characteristics using the bulk wave in the thickness shear mode excited in the piezoelectric layer 2. In the acoustic wave device 1, in a case where d is the thickness of the piezoelectric layer 2 and p is the center-to-center distance between any adjacent electrodes 3 and 4 among the plurality of pairs of electrodes 3 and 4, d/p is, for example, about 0.5 or less. As a result, the bulk wave in the thickness shear mode is effectively excited, and good resonance characteristics can be obtained. More preferably, d/p is, for example, about 0.24 or less, and in this case, better resonance characteristics can be obtained.

In the acoustic wave device 1, since the above-described configuration is provided, even in a case where the number of pairs of the electrodes 3 and 4 is reduced in order to reduce the size, the Q value is unlikely to be decreased. This is because the propagation loss is small even in a case where the number of electrode fingers in the reflectors on both sides is small. In addition, the number of electrode fingers can be reduced by using the bulk wave in the thickness shear mode. A difference between the Lamb wave used in the acoustic wave device and the bulk wave in the thickness shear mode will be described with reference to FIGS. 16A and 16B.

FIG. 16A is a schematic elevational cross-sectional view showing the Lamb wave that propagates through the piezoelectric film of the acoustic wave device as disclosed in Japanese Unexamined Patent Application Publication No. 2012-257019. Here, the wave propagates in a piezoelectric film 201 as indicated by an arrow. Here, in the piezoelectric film 201, a first main surface 201a and a second main surface 201b oppose each other, and a thickness direction connecting the first main surface 201a and the second main surface 201b is a Z direction. An X direction is a direction in which the electrode fingers of the IDT electrodes are arranged. As shown in FIG. 16A, in the Lamb wave, the wave propagates in the X direction as shown in the figure. Since the wave is a plate wave, although the piezoelectric film 201 vibrates as a whole, since the wave propagates in the X direction, the reflectors are disposed on both sides to obtain the resonance characteristics. Therefore, the propagation loss of the wave occurs, and the Q value is decreased in a case where the size reduction is attempted, that is, in a case where the number of pairs of the electrode fingers is decreased.

On the other hand, as shown in FIG. 16B, in the acoustic wave device 1, since the vibration displacement is a thickness shear direction, the wave propagates and resonates in the direction connecting the first main surface 2a and the second main surface 2b of the piezoelectric layer 2, that is, the Z direction. That is, an X-direction component of the wave is significantly smaller than a Z-direction component. In addition, since the resonance characteristics are obtained by the propagation of the wave in the Z direction, the propagation loss is unlikely to occur even when the number of the electrode fingers of the reflector is reduced. Further, even in a case where the number of pairs of the electrode pair consisting of the electrodes 3 and 4 is reduced when the size reduction is attempted, the Q value is unlikely to be decreased.

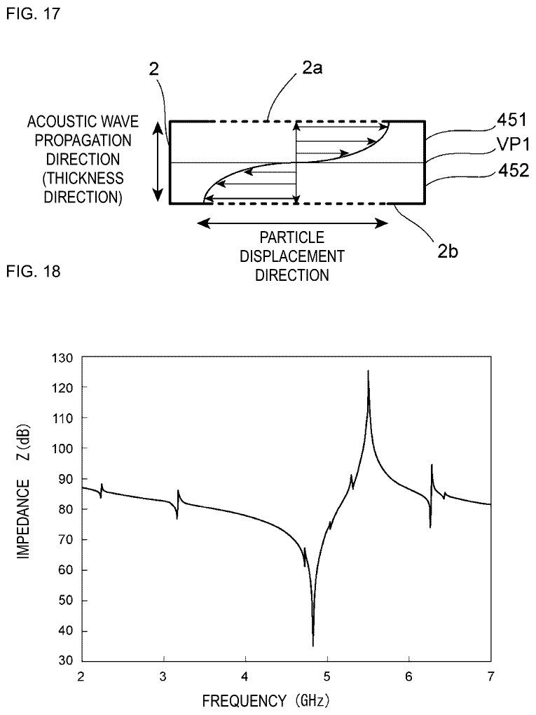

Amplitude directions of the bulk waves of the thickness shear mode are opposite to each other between a first region 451 included in the excitation region C of the piezoelectric layer 2 and a second region 452 included in the excitation region C, as shown in FIG. 17. FIG. 17 schematically shows the bulk waves when the voltage is applied between the electrodes 3 and 4 so that the potential of the electrode 4 is higher than the potential of the electrode 3. The first region 451 is a region of the excitation region C between a virtual plane VP1, which is orthogonal to the thickness direction of the piezoelectric layer 2 and bisects the piezoelectric layer 2, and the first main surface 2a. The second region 452 is a region of the excitation region C between the virtual plane VP1 and the second main surface 2b.

As described above, in the acoustic wave device 1, although at least the pair of electrodes including the electrodes 3 and 4 is disposed, the waves are not propagated in the X direction, and thus the number of pairs of the electrode pair including the electrodes 3 and 4 does not have to be plural. That is, at least the pair of electrodes need only be provided.

For example, the electrode 3 is connected to a hot potential and the electrode 4 is connected to a ground potential. However, the electrode 3 may be connected to the ground potential and the electrode 4 may be connected to the hot potential. In the acoustic wave device 1, at least a pair of electrodes is the electrodes connected to the hot potential or the electrodes connected to the ground potential, as described above, and no floating electrodes are provided.

FIG. 18 is a view showing the resonance characteristics of the acoustic wave device shown in FIG. 15. The design parameters of the acoustic wave device 1 with the resonance characteristics are as follows.

Piezoelectric layer 2: LiNbO₃ with Euler angles (0°, 0°,) 90°, thickness=about 400 nm.

When viewed in the direction orthogonal to the length direction of the electrodes 3 and 4, the length of the region in which the electrodes 3 and 4 overlap each other, that is, the length of the excitation region C=about 40 μm, the number of pairs of the electrodes consisting of the electrodes 3 and 4=21 pairs, the distance between the center of the electrodes=3 μm, the width of the electrodes 3 and 4=about 500 nm, and d/p=about 0.133.

Insulating layer 7: silicon oxide film having a thickness of about 1 μm.

Support portion 8: Si.

The length of the excitation region C is the dimension along the length direction of the electrodes 3 and 4 of the excitation region C.

In the acoustic wave device 1, an electrode-to-electrode distance of the electrode pair including the electrodes 3 and 4 is made equal or substantially equal in all the plurality of pairs. That is, the electrodes 3 and 4 are disposed at equal or substantially equal pitches.

As is clear from FIG. 18, good resonance characteristics with the fractional bandwidth of about 12.5% are obtained regardless of the presence of the reflector.

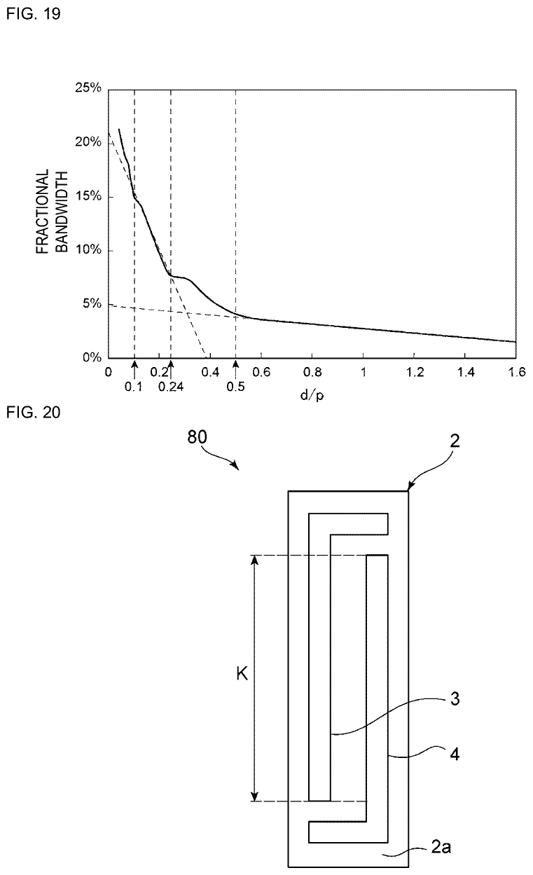

For example, in a case where the thickness of the piezoelectric layer 2 is d and the center-to-center distance of the electrodes 3 and 4 is p, in the acoustic wave device 1, as described above, d/p is about 0.5 or less, more preferably about 0.24 or less. The description thereof will be made with reference to FIG. 19.

A plurality of acoustic wave devices are obtained by changing d/p in the same manner as the acoustic wave device that obtains the resonance characteristics shown in FIG. 18. FIG. 19 is a view showing a relationship between d/p and the fractional bandwidth as the resonator of the acoustic wave device.

As is clear from FIG. 19, when d/p >about 0.5, the fractional bandwidth is less than about 5% even in a case where d/p is adjusted. On the other hand, in a case where d/p ≤about 0.5, when d/p is changed within this range, the fractional bandwidth of about 5% or more can be obtained, that is, the resonator having a high coupling coefficient can be formed. In addition, in a case where d/p is about 0.24 or less, the fractional bandwidth can be increased to about 7% or more. In addition, by adjusting d/p within this range, a resonator with a wider fractional bandwidth can be obtained, and a resonator with a higher coupling coefficient can be realized. Therefore, it is found that, by adjusting d/p to about 0.5 or less, it is possible to configure a resonator having a high coupling coefficient using the bulk wave in the thickness shear mode.

FIG. 20 is a plan view of the acoustic wave device using the bulk wave in the thickness shear mode. In an acoustic wave device 80, the pair of electrodes including the electrode 3 and electrode 4 is provided on the first main surface 2a of the piezoelectric layer 2. K in FIG. 20 is a cross width. As described above, in the acoustic wave device according to the present invention, the number of pairs of the electrodes may be one pair. Even in this case, when d/p is about 0.5 or less, it is possible to effectively excite the bulk wave in the thickness shear mode.

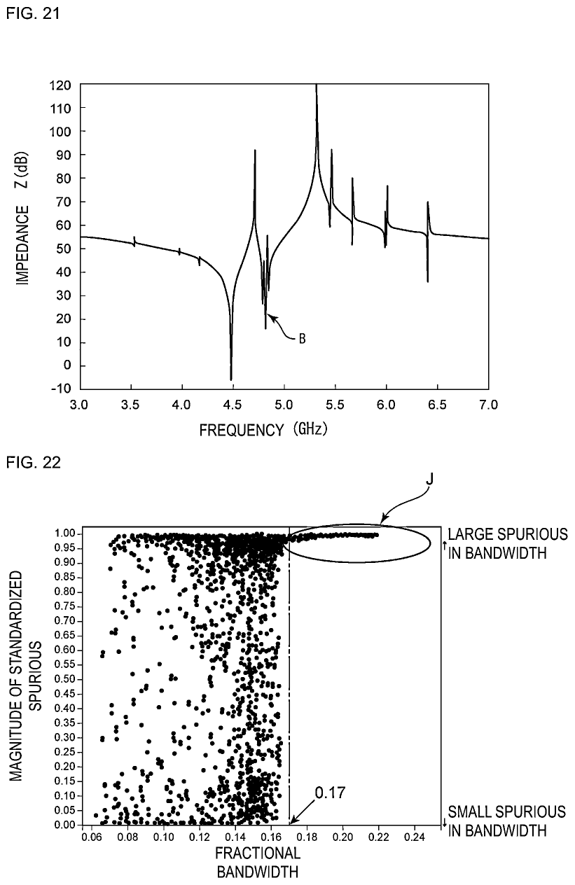

In the acoustic wave device 1, it is preferable that the metallization ratio MR of any adjacent electrodes 3 and 4 among the plurality of electrodes 3 and 4 to the excitation region C, which is the region in which the adjacent electrodes 3 and 4 overlap each other when viewed in the opposing direction, satisfies MR ≤ about 1.75 (d/p)+0.075. In this case, the spurious wave can be effectively reduced. The description thereof will be made with reference to FIGS. 21 and 22. FIG. 21 is a reference view showing an example of the resonance characteristics of the acoustic wave device 1. The spurious wave indicated by an arrow B appears between the resonant frequency and the anti-resonant frequency. It should be noted that d/p=0.08 and the Euler angles of LiNbO₃ are (0°, 0°,) 90°. Also, the metallization ratio MR is about 0.35.

The metallization ratio MR will be described with reference to FIG. 14B. In the electrode structure of FIG. 14B, it is assumed that, when focusing on the pair of electrodes 3 and 4, only the pair of electrodes 3 and 4 is provided. In this case, a portion surrounded by a one-dot chain line is the excitation region C. The excitation region C is a region of the electrode 3 that overlaps the electrode 4 when the electrode 3 and the electrode 4 are viewed in the direction orthogonal to the length direction of the electrodes 3 and 4, that is, in the opposing direction, a region of the electrode 4 that overlaps the electrode 3, and a region in which the electrode 3 and the electrode 4 overlap each other in the region between the electrode 3 and the electrode 4. An area of the electrodes 3 and 4 in the excitation region C with respect to an area of this excitation region C is the metallization ratio MR. That is, the metallization ratio MR is a ratio of an area of the metallization portion to the area of the excitation region C.

In a case where the plurality of pairs of electrodes are provided, a ratio of the metallization portion included in the entire excitation region to a total area of the excitation region need only be MR.

FIG. 22 is a view showing a relationship between a fractional bandwidth and a phase rotation amount of an impedance of the spurious wave standardized at about 180 degrees as a magnitude of the spurious wave in a case where a large number of acoustic wave resonators are configured according to the configuration of the acoustic wave device 1. It should be noted that the fractional bandwidth is adjusted by changing the film thickness of the piezoelectric layer and the dimensions of the electrodes. Moreover, FIG. 22 shows the results in a case where the piezoelectric layer made of the Z-cut LiNbO₃ is used, but the same tendency is obtained in a case where piezoelectric layers with other cut-angles are used.

In a region surrounded by an ellipse J in FIG. 22, the spurious wave is as large as about 1.0. As is clear from FIG. 22, in a case where the fractional bandwidth exceeds about 0.17, that is, exceeds about 178, a large spurious wave with a spurious wave level of about 1 or more appears in a pass band even when the parameters constituting the fractional bandwidth are changed. That is, as in the resonance characteristics shown in FIG. 21, a large spurious wave indicated by an arrow B appears within the band. Therefore, for example, the fractional bandwidth is preferably about 17% or less. In this case, by adjusting the film thickness of the piezoelectric layer 2 and the dimensions of the electrodes 3 and 4, the spurious wave can be reduced.

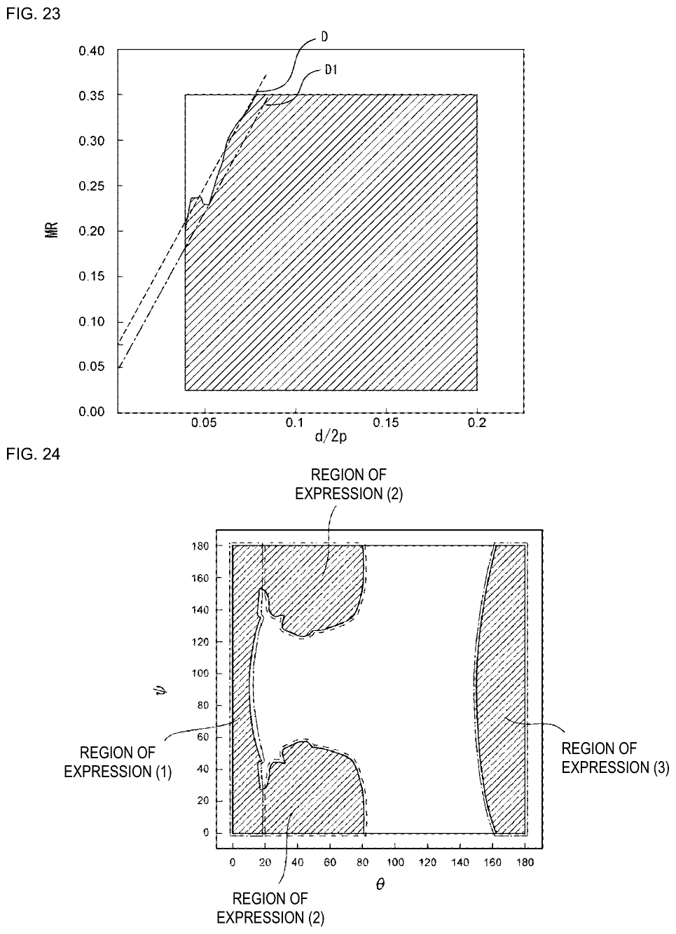

FIG. 23 is a view showing a relationship between d/2p, the metallization ratio MR, and the fractional bandwidth. In the acoustic wave device described above, various acoustic wave devices having different d/2p and MR are configured, and the fractional bandwidth is measured. A hatched portion on a right side of a broken line D in FIG. 23 is a region in which the fractional bandwidth is about 17% or less. A boundary between the hatched region and a non-hatched region is expressed by MR=about 3.5 (d/2p)+0.075. That is, MR=about 1.75 (d/p)+0.075. Therefore, for example, preferably, MR<about 1.75 (d/p)+0.075. In this case, it is easy to set the fractional bandwidth to about 17% or less.

More preferably, for example, it is a region on a right side of MR=about 3.5 (d/2p)+0.05 indicated by a one-dot chain line D1 in FIG. 23. That is, in a case where MR≤ about 1.75 (d/p)+0.05, the fractional bandwidth can be reliably set to about 17% or less.

FIG. 24 is a view showing a map of the fractional bandwidth with respect to Euler angles (0°, θ, ψ) of LiNbO₃ in a case where d/p is infinitely close to 0. A hatched portion in FIG. 24 is a region in which the fractional bandwidth of at least about 5% or more is obtained, and in a case where a range of the region is approximated, the range is a range represented by Expressions (1), (2), and (3).
(0°+10°, 0° to 20°, any ψ) . . . . Expression (1)
(0°+10°, 20° to 80°, 0° to 60° (1-(θ-50)²/900)^{1/2}) or (0°±10°, 20° to 80°, [180°−60° (1-(θ-50)²/900)^{1/2}] to) 180° . . . . Expression (2)
(0°+10°, [180°−30° (1-(ψ-90)²/8100)^{1/2}] to 180°, any ψ) . . . . Expression (3)

Therefore, in a case of the Euler angle range of Expression (1), Expression (2), or Expression (3), the fractional bandwidth can be sufficiently widened, which is preferable. The same applies to a case where the piezoelectric layer 2 is the lithium tantalate layer.

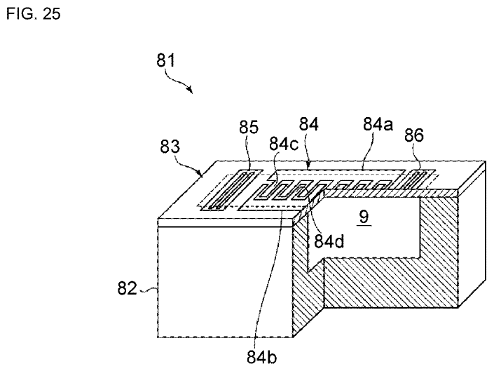

FIG. 25 is a partially cutaway perspective view showing the acoustic wave device using the Lamb wave.

An acoustic wave device 81 includes a support substrate 82. The support substrate 82 is provided with a recess portion that is open on an upper surface. A piezoelectric layer 83 is laminated on the support substrate 82. As a result, a cavity portion 9 is provided. An IDT electrode 84 is provided on the piezoelectric layer 83 above the cavity portion 9. Reflectors 85 and 86 are provided on both sides of the IDT electrode 84 in an acoustic wave propagation direction. In FIG. 25, an outer periphery edge of the cavity portion 9 is indicated by a broken line. Here, the IDT electrode 84 includes first and second busbars 84a and 84b, a plurality of first electrode fingers 84c, and a plurality of second electrode fingers 84d. The plurality of first electrode fingers 84c are connected to the first busbar 84a. The plurality of second electrode fingers 84d are connected to the second busbar 84b. The plurality of first electrode fingers 84c and the plurality of second electrode fingers are 84d interdigitated between each other.

In the acoustic wave device 81, the Lamb wave as the plate wave is excited by applying an AC electric field to the IDT electrodes 84 on the cavity portion 9. Since the reflectors 85 and 86 are provided on both sides, the resonance characteristics caused by the Lamb wave can be obtained.

As described above, an acoustic wave device according to an example embodiment of the present invention may use the plate wave. In the example shown in FIG. 25, the IDT electrode 84, the reflector 85, and the reflector 86 are provided on the main surface of the piezoelectric layer 14 corresponding to the second main surface 14b shown in FIG. 2 and the like. In a case where the acoustic wave device according to this example embodiment of the present invention uses the plate wave, the IDT according to the present invention and the reflector 85 and the reflector 86 shown in FIG. 25 need only be provided on the first main surface 14a of the piezoelectric layer 14 in the acoustic wave device according to the first to third example embodiments.

In the acoustic wave devices according to the first to third example embodiments that use the bulk wave in the thickness shear mode, as described above, d/p is, for example, preferably about 0.5 or less, and more preferably about 0.24 or less. As a result, better resonance characteristics can be obtained. Further, in the excitation regions in the acoustic wave devices according to the first to third example embodiments that use the bulk wave in the thickness shear mode, as described above, for example, preferably, MR≤ about 1.75 (d/p)+0.075 is satisfied. In this case, it is possible to more reliably suppress the spurious wave.

It is preferable that the piezoelectric layers in the acoustic wave devices according to the first to third example embodiments that use the bulk wave in the thickness shear mode are, for example, the lithium niobate layer or the lithium tantalate layer. In addition, it is preferable that the Euler angles (o, 0, of lithium niobate or lithium tantalate forming the piezoelectric layer are in the range of Expression (1), Expression (2), or Expression (3). In this case, the fractional bandwidth can be sufficiently widened.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a support portion including a support substrate;
a piezoelectric layer on the support portion and including a first main surface located on a support portion side and a second main surface opposing the first main surface; and
at least one interdigital transducer (IDT) on the first main surface of the piezoelectric layer and including a plurality of electrode finger portions; wherein
a cavity portion surrounded by the support portion and the piezoelectric layer is provided;
the plurality of electrode finger portions of the at least one IDT are located in the cavity portion, and a through hole is provided in the piezoelectric layer to extend to the cavity portion; and
in the plurality of electrode finger portions of the at least one IDT, a dimensional relationship is provided in at least one set of the electrode finger portions, the dimensional relationship being a relationship in which at least a portion of an electrode finger portion at a position closer to the through hole in one set of the electrode finger portions has a smaller thickness and a larger width than at least a portion of an electrode finger portion at a position farther from the through hole.

2. The acoustic wave device according to claim 1, wherein
when viewed from a direction orthogonal or substantially orthogonal to a direction in which the plurality of electrode finger portions extend, a region in which the electrode finger portions adjacent to each other overlap each other is a cross region of the IDT; and
where a portion of the cross region that is about 80% of a center in the direction in which the plurality of electrode finger portions extend is a center portion, the dimensional relationship is between all of portions of one set of the electrode finger portions located in the center portion.

3. The acoustic wave device according to claim 1, wherein
a plurality of the through holes are provided in the piezoelectric layer; and
the dimensional relationship is provided for each of the through holes in at least one set of the electrode finger portions.

4. The acoustic wave device according to claim 1, wherein the electrode finger portion is an electrode finger made of at least one metal layer.

5. The acoustic wave device according to claim 1, wherein the electrode finger portion includes an electrode finger made of at least one metal layer, and a dielectric layer laminated on the electrode finger.

6. The acoustic wave device according to claim 1, wherein the acoustic wave device is configured to use a plate wave.

7. The acoustic wave device according to claim 1, wherein the acoustic wave device is configured to use a bulk wave in a thickness shear mode.

8. The acoustic wave device according to claim 1, wherein, in a case where a thickness of the piezoelectric layer is d and a center-to-center distance of the electrode finger portions adjacent to each other is p, d/p is about 0.5 or less.

9. The acoustic wave device according to claim 8,
wherein d/p is about 0.24 or less.

10. The acoustic wave device according to claim 8, wherein
a region, which is a region in which the electrode finger portions adjacent to each other overlap each other when viewed from a direction orthogonal or substantially orthogonal to a direction in which the plurality of electrode finger portions extend and is a region between centers of the electrode finger portions adjacent to each other, is an excitation region; and
in a case where a metallization ratio of the plurality of electrode finger portions with respect to the excitation region is MR, MR≤ about 1.75 (d/p)+0.075 is satisfied.

11. The acoustic wave device according to claim 1, wherein the piezoelectric layer is made of lithium niobate or lithium tantalate.

12. The acoustic wave device according to claim 7, wherein
the piezoelectric layer is made of lithium niobate or lithium tantalate; and
Euler angles (φ, θ, ψ) of the lithium niobate or the tantalum niobate forming the piezoelectric layer are in a range of one or more of:
(0°±10°, 0° to 20°, any ψ);
(0°±10°, 20° to 80°, 0° to 60° (1-(θ-50)²/900)^{1/2}) or (0°±10°, 20° to 80°, [180°-60° (1-(θ-50)²/900)^{1/2}] to) 180°; and
(0°±10°, [180°−30° (1-(ψ-90)²/8100)^{1/2}] to 180°, any ψ).

13. The acoustic wave device according to claim 1, wherein
the support portion includes an insulating layer between the support substrate and the piezoelectric layer; and
the insulating layer and the piezoelectric layer are located such that a portion of the insulating layer and a portion of the piezoelectric layer oppose each other with the cavity portion interposed therebetween.

14. The acoustic wave device according to claim 1, wherein the plurality of electrode finger portions are defined by a multilayer body including a metal layer and a dielectric layer.

15. The acoustic wave device according to claim 1, wherein at least one via hole is defined in a portion of the piezoelectric layer which overlaps a portion of the at least one IDT in plan view.

16. The acoustic wave device according to claim 1, wherein a frequency adjustment film is provided on a main surface of the piezoelectric layer to overlap a portion of the at least one IDT in plan view.

17. The acoustic wave device according to claim 1, wherein the thickness of the piezoelectric layer is about 40 nm or more and about 1000 nm or less.
